(19) United States
(12) Patent Application Publication
(10) Pub. No.: US 2025/0113466 A1
(43) Pub. Date: Apr. 3, 2025

(54) VEHICLE THERMAL MANAGEMENT SYSTEM AND AUTONOMOUS VEHICLES

(71) Applicant: AutoX, Inc., Grand Cayman (KY)

(72) Inventors: Wenchun Lv, Shenzhen (CN); Cheng Liu, Shenzhen (CN); Zhong Cen, Shenzhen (CN); Jianqiang Zhang, Shenzhen (CN); Huasen Li, Shenzhen (CN); Tao Shi, Shenzhen (CN)

(73) Assignee: AutoX, Inc., Grand Cayman (KY)

(21) Appl. No.: 18/900,802

(22) Filed: Sep. 29, 2024

(30) Foreign Application Priority Data
Sep. 28, 2023 (CN) 2023112852868

(51) Int. Cl. H05K 7/20; B60R 16/08; G08B 21/18

(52) U.S. Cl. CPC H05K 7/20872; B60R 16/08; G08B 21/182

(57) ABSTRACT

A vehicle thermal management system provided includes a water tank, a flow channel plate, a power component, and a flow channel control component. The water tank includes a plurality of chambers with a first chamber and a second chamber filled with liquid; the flow channel plat includes a plurality of channels connected to the chambers to form thermal management loop to respectively control the first group of the component and the second group of the components; the power assembly includes a first power component and a second power component, respectively arranged on the first thermal management loop and the second thermal management loop; the flow channel control assembly includes a first flow channel control component and a second flow channel control component respectively arranged on the first thermal management loop and the second thermal management loop, and selectively controlling on/off status of them.

This non-provisional patent application claims priority under 35 U.S.C. § 119 from Chinese Patent Application No. 2023112852868 filed on Sep. 28, 2023, the entire content of which is incorporated herein by reference.

### TECHNICAL FIELD

This disclosure relates to vehicle technologies, particularly to a vehicle thermal management system and an autonomous driving vehicle.

### BACKGROUND

As technology continues to update and iterate, emerging vehicles, such as autonomous vehicles, are gaining prominence. The chips employed in autonomous vehicles are becoming more powerful, leading to power consumption, and improve the heating efficiency. Therefore, it is necessary to timely carry out heat dissipation processing for the data processing chips. Furthermore, the autonomous vehicles rely on various perception sensors and ultra-powerful computing domain controllers. During operation, the autonomous vehicles must effectively dissipate heat generated by both the sensors and ultra powerful computing domain controllers. In addition, the normal operating temperature standards differ among data processing chips, sensors, and ultra high computing power domain controllers.

The heat dissipation measures commonly employed in current autonomous vehicles are generally categorized into air cooling, water cooling, and direct cooling. Among these, the air cooling method is constrained by factors such as size, noise, and vibration and struggles to accommodate the rapid iteration of new technologies. The direct cooling approach, on other hand, suffers from drawbacks like poor reliability, stringent structural requirements, and challenges in adapting to varying seasonal conditions. In contrast, the water cooling scheme boasts advantages like compact size, robust reliability, energy recovery, and strong compatibility. Therefore, it is advisable to adopt a water-cooled solution for the autonomous driving domain controller and sensors. However, the existing water cooling schemes primarily focus on managing overall heat of the vehicle, falling to adequately address the specific needs of the autonomous driving vehicles. Additionally, there are also passive cooling schemes designed for the autonomous driving vehicles that uniformly cool all temperature-controlled devices. As a result, the temperature of some temperature controlled devices is inconsistent with the normal operating temperature standard. Therefore, the current water cooling schemes are unable to effectively regulate the temperature controlled devices to the corresponding normal operating temperature standards.

### SUMMARY

This disclosure provides a vehicle thermal management system and an autonomous driving vehicle that can achieve both vehicle thermal management and multi configuration management.

Firstly, the disclosure provides a vehicle thermal management system includes a water tank, a flow channel plate, a power component, and a flow channel control component. The components requiring temperature control includes a first group of components requiring temperature control, and a second group of components requiring temperature control. The water tank includes a plurality of chambers consisting of a first chamber and a second chamber filled with liquid. The flow channel plate includes a plurality of channels connected to the chambers, forming thermal management loops, the thermal management loops consists of a first thermal management loop and a second thermal management loop to respectively control the first group of the components and the second group of the components. The power assembly includes a first power component and a second power component. respectively arranged on the first thermal management loop and the second thermal management loop, to pump liquid from the corresponding chambers into the first thermal management loop and/or the second thermal management loops. The flow channel control assembly includes a first flow channel control component and a second flow channel control component, respectively arranged on the first thermal management loop and the second thermal management loop, enabling selective activation and deactivation of the first thermal management loop and the second thermal management loop.

Secondly, the disclosure also provides an autonomous driving vehicle comprising a vehicle body and a vehicle thermal management system set on the vehicle body.

The above vehicle thermal management system, when integrated with autonomous driving vehicles, features multiple thermal management loops, enabling the selection of one or more effective thermal management loops based on actual operational requirements. Furthermore, the ability to control multiple thermal management loops independently facilitates both comprehensive vehicle thermal management and consideration of various thermal management loop configurations, thereby enhancing overall flexibility. Additionally, by enabling separate control the multiple thermal management loops, the system ensures more precise temperature regulation for each group of temperature controlled devices.

### BRIEF DESCRIPTION OF THE DRAWINGS

In order to better illustrate the technical solutions in the embodiments or prior art of the present application, a brief introduction will be given below to the accompanying drawings required in the embodiments or prior art description. It is evident that the accompanying drawings in the following description are only some embodiments of the present application,

For ordinary technical personnel in this field, other drawings can be obtained based on the structures shown in these drawings without creative labor.

FIG. 1 illustrates an internal view of an vehicle thermal management system with a water tank provided in an embodiment.

FIG. 2a illustrates an internal view of the water tank provided in a first embodiment of the present application.

FIG. 2b illustrates an internal view of the water tank provided in a second embodiment of the present application.

FIG. 3 illustrates a principle diagram of the vehicle thermal management system provided in a first embodiment.

FIG. 4 illustrates a principle diagram of the vehicle thermal management system provided in a second embodiment.

FIG. 5 illustrates a principle diagram of the vehicle thermal management system provided in a third embodiment.

FIG. 6 illustrates a principle diagram of the vehicle thermal management system provided in a fourth embodiment.

FIG. 7 illustrates a principle diagram of the vehicle thermal management system provided in a fifth embodiment.

FIG. 8 illustrates a perspective view of the vehicle thermal management system with a cooling and heating in an embodiment.

FIG. 9 illustrates is an exploded view of the vehicle thermal management shown in FIG. 8.

FIG. 10 illustrates a perspective view of the vehicle thermal management system with a single cooling configuration in an embodiment.

FIG. 11 illustrates an autonomous driving vehicle provided in an embodiment

The implementation, functional characteristics, and advantages of the purpose of this application will be further explained in conjunction with the embodiments, with reference to the accompanying drawings.

### DETAILED DESCRIPTION OF THE EMBODIMENTS

In order to make the purpose, technical solution, and advantages of this application clearer and clearer, the following will provide further detailed explanations of this application in conjunction with the accompanying drawings and embodiments. It should be understood that the specific embodiments described here are only intended to explain the present application and are not intended to limit the present application. Based on the embodiments in this application, all other embodiments obtained by ordinary technical personnel in this field without creative labor fall within the scope of protection of this application.

The terms “first”, “second”, “third”, “fourth”, etc. (if any) in the specification and claims of this application, as well as the accompanying drawings, are used to distinguish similar planning objects and do not need to be used to describe specific order or sequence. It should be understood that the data used in this way can be interchanged in appropriate cases, in other words, the described embodiments are implemented in order other than those illustrated or described here. In addition, the terms “including” and “having”, as well as any variations thereof, may also include other content, such as processes, methods, systems, products, or equipment that include a series of steps or units, not necessarily limited to those clearly listed, but may include other steps or units that are not clearly listed or inherent to these processes, methods, products, or equipment.

It should be noted that the descriptions related to “first”, “second”, etc. in this application are only for descriptive purposes and cannot be understood as indicating or implying their relative importance or implying the quantity of technical features indicated. Therefore, the features limited to “first” and “second” can explicitly or implicitly include one or more of these features. In addition, the technical solutions between various embodiments can be combined with each other, but must be based on what ordinary technical personnel in the art can achieve. When the combination of technical solutions conflicts or cannot be achieved, it should be considered that the combination of such technical solutions does not exist and is not within the scope of protection required by this application.

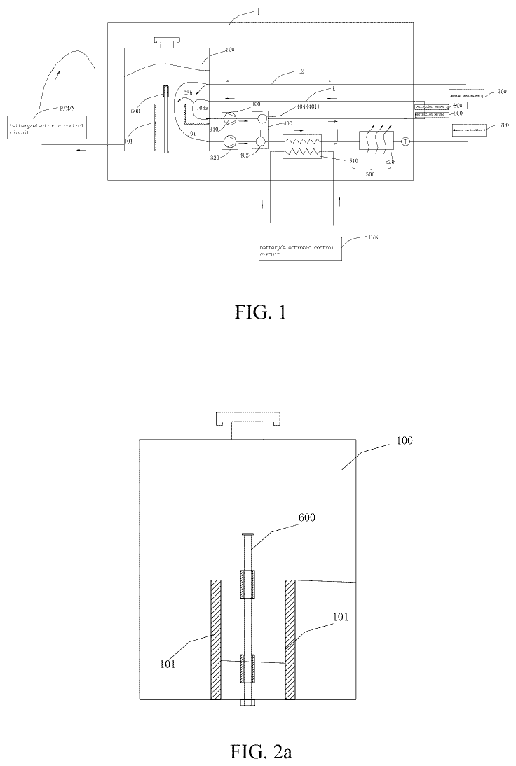

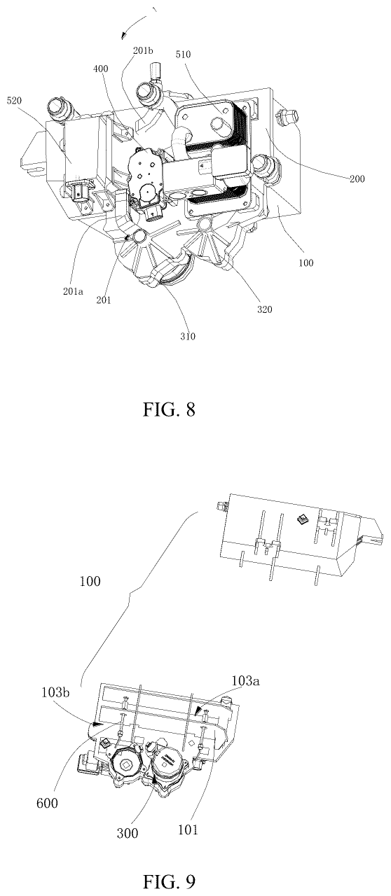

Referring to FIGS. 1 and 8, a perspective view of a vehicle thermal management system 1 is illustrated. FIG. 1 shows an internal view of the vehicle thermal management system 1. The vehicle thermal management system 1 includes a plurality of thermal management loops. During use, one or more thermal management loops can employ one or more thermal management loops to perform thermal management on autonomous vehicles. In other words, it can configure the autonomous driving vehicle to have only one thermal management loop, based on the specific thermal management needs of the vehicle, and unify the thermal management of all temperature-controlled devices connected to that loop. Alternatively, it can enable the autonomous driving vehicle to operate with a plurality loop simultaneously, allowing for separate thermal management of component requiring temperature control assigned to each thermal management loop for thermal management. In this manner, the vehicle thermal management system 1 accomplishes both comprehensive vehicle thermal management and multi configuration management of vehicle thermal management. The following example illustrate how the vehicle thermal management system 1 has two thermal management loops, specifically, a first thermal management loop and a second thermal management loop. It should be note that, the vehicle thermal management system 1 can also include two or more circuits, such as a third thermal management loop, a fourth thermal management loop, among them, it will not list them all here. In this embodiment, the components requiring temperature control refers to the components requiring temperature control that requires thermal management, including but not limited to a battery P, a motor M, an electronic control circuit N, a domain controller 700, a perception sensor 800, etc.

The vehicle thermal management system 1 includes a water tank 100, a flow plate 200, a power component 300, a flow control component 400, a heat exchanger assembly 500, and a liquid level sensor 600. The water tank 100 is configured to store liquid used for thermal management purposes. The channel plate 200 defines several channels 201 connected to the water tank 100 to form a first thermal management loop L1 and a second thermal management loop L2. The power assembly 300 is configured to pump the liquid from the water tank 100 into various flow channels 201. The flow control component 400 is configured to manage activation/deactivation of both the first thermal management loop L1 and the second thermal management loop L2. Specifically, the flow control component 400 is maintain one of first thermal management loop L1 and the second thermal management loop L2 closed, while the other intermittently is opened and closed, allowing the autonomous vehicle have single, controllable thermal management loop ate a time. Alternatively, the flow control component 400 can intermittently open and close both the first thermal management loop L1 and the second thermal management loop L2 enabling the autonomous driving vehicle to have two independently controllable thermal management loops.

In this embodiment, a plurality of divider parts 101 are located in the water tank 100. For example, two or more divider parts 101, so that the water tank 100 is divided into a plurality of chambers 103. A height value of divider parts 101 is smaller than a height of the water tank 100 along the height direction of divider parts 101, resulting in a certain gap between the chambers 103 and the water tank 100. In this embodiment, the liquid level in water tank 100 is higher than the height of divider parts 101, so that the liquid level in each chamber 103 is the same. It can be understood that in some other embodiments, the liquid level in each chamber 103 may be different. For example, in some other embodiments, the divider parts 101 can be used to completely separate the water tank 100, so that there is no gap between each chamber 103 and the water tank 100, thereby ensuring that the liquid between each chamber 103 is not affected by the liquid level in another chamber 103. For example, in some other embodiments, partial chambers 103 may not be completely separated from each other. In this embodiment, as the vehicle thermal management system 1 includes a first thermal management loop L1 and a second thermal management loop L2, correspondingly, the chambers 103 includes a first chamber 103a and a second chamber 103b. The first thermal management loop L1 and the second thermal management loop L2 correspond to the first chamber 103a and the second chamber 103b, respectively. In this embodiment, the liquid can be water, coolant, or other substances used for cooling, without limitation here. At a high liquid level, the cooling liquid at different temperatures is fully mixed with each chamber in the water tank 100, which can achieve a certain heat exchange effect. The heating power is not high, and a certain temperature of cooling liquid can be provided for heat pipe control in circuits that are not sensitive to the water temperature in the intermediate temperature zone.

The flow channels 201 include the main channel 201a and the branch channel 201b. In this embodiment, the main channel 201a is a flow channel coupled to the chamber 103. The branch channel 201b is communicated with the main channel 201a. The main channel 201a and the branch channel 201b form the first thermal management loop L1 or the second thermal management loop L2 according to a predetermined layout. That is to say, the first thermal management loop L1 or the second thermal management loop L2 can be composed of the main flow channel 201a and the branch flow channel 201b. In this embodiment, an end of the main channel 201a connected to the chamber 103 remains below the liquid level, so that the first thermal management loop L1 or the second thermal management loop L2 will not draw in air. In this example, control ports 2010 are disposed at the main channel 201a and the branch channel 201b for coordination with the channel control component 400, as described below.

In this embodiment, the power assembly 300 includes a plurality of water pumps. In this embodiment, the power assembly 300 includes a first water pump 310 and a second water pump 320. The first water pump 310 and the second water pump 320 are respectively coupled to the first thermal management loop L1 and the second thermal management loop L2 to pump the liquid in the first chamber 103a and the second chamber 103b to the corresponding flow channel 201, so that the liquid can flow in the first thermal management loop L1 and the second thermal management loop L2.

In this embodiment, the channel control component 400 includes a first channel control component and a second channel control component. The first channel control component is configured to turn on and off the first thermal management loop L1. The second channel control component is configured to turn on and off the second thermal management loop L2. In this embodiment, the first and second channel control components are also components that enable the autonomous driving vehicle to have one or two thermal management loops.

For example, the autonomous vehicles employ a single-loop thermal management configuration, which means that only one thermal management loop is required. This allows for either the first thermal management loop L1 or the second thermal management loop L2 to be permanently closed, rendering one of the first thermal management loop L1 and the second thermal management loop L2 inactive, while the other loop remains active, operating intermittently to open and close as needed for thermal management purposes, facilitating the flow or blockage of fluids, and thus managing the temperature of the component requiring temperature control within the of the first thermal management loop L1 and the second thermal management loop L2. Specifically, taking the single-loop thermal management configuration as an illustration, assume the first thermal management loop L1 is the inactive loop, while the second thermal management loop L2 is the active loop. In this embodiment, the first flow channel control component includes a blocking assembly 401. The blocking assembly 401 is used to block the flow channel of the first thermal management loop L1, preventing fluid flow and thereby rendering the first thermal management loop L1 inactive. In some alternative embodiments, the first flow channel control component includes a plurality of valve switches 402, each with an open and closed state. In this embodiment, one or more of the first valve switches 402 remain permanently closed, preventing fluid flow in the first thermal management loop L1 and thus rendering it inactive. Preferably, one or more the first valve switches 402 located at the main flow channel 201a, are kept in a permanently closed state, ensuring no fluid flows through the first thermal management loop L1 when the one or more the first valve switches are closed. Correspondingly, the second flow channel control component s includes a plurality of second valve switches 404, each with an open and closed state. Each of the second valve switch 404 controls the flow of fluid into or stops the flow from various branch flow channels 201b, thereby managing the temperature of components requiring temperature control located on the corresponding branch flow channels 201b.

For another example, since the components requiring temperature control have varying operating temperature standards, different thermal management schemes need to adopted for thermal management, which means that each component requiring temperature control should be thermally managed according to distinct thermal management scheme. In other words, the components requiring temperature control are categorized based on the working temperature standards, with the components requiring temperature control having similar working temperature standards grouped together, and the components requiring temperature control with significant differences working temperature standards grouped separately. In this embodiment, taking an example where the components requiring temperature control are divided into two groups. The first group of the components requiring temperature control is thermally managed by the first thermal management loop L1, and the second group of the components requiring temperature control is thermally managed by the second thermal management loop L2. That is to say, both the first thermal management loop L1 and the second thermal management loop L2 are functional. The first channel control component includes a plurality of first valve switches 402, each of which includes an open and closed state. In this embodiment, the first valve switches 402 intermittently open and close, thereby controlling the flow of liquid to each branch flow channel 201b of the first thermal management loop L1 or stopping the flow to each branch flow channel 201b of the first thermal management loop L1, thereby performing thermal management on the components requiring temperature control on each branch flow channel 201b. Correspondingly, the second channel control component includes a plurality of second valve switches 404, each of which includes an open and closed state. The second valve switches 404 control the flow of liquid to each branch flow channel 201b or stops flowing to each branch flow channel 201b, thereby performing thermal management on the components requiring temperature control on each branch flow channel 201b.

It can be understood that if in the specific design process, one of the branch channels 201b are not required, the sealing component 401 can also be utilized for sealing purposes.

In this embodiment, the flow control component 400 activates or deactivates the first thermal management loop L1 or the second thermal management loop L2, and controls the opening and closing of each of the main flow channels 201a and the branch flow channels 201b within active the first thermal management loop L1 or the second thermal management loop L2 By doing so, the vehicle thermal management system 1 can be configured in various forms, enabling flexible setup and adaptability to diverse thermal management scheme requirements.

In this embodiment, the heat exchanger assembly 500 includes a refrigeration heat exchanger 510 and a heating heat exchanger 520. In this embodiment, it is only illustrated that the refrigeration heat exchanger 510 and the heating heat exchanger 520 are arranged in parallel on the first thermal management loop L1, that is, the first thermal management loop L1 operates in both a cold mode and a warm mode. In some embodiments, the refrigeration heat exchanger 510 and the heating heat exchanger 520 can also be arranged in parallel in the second heat management circuit L2, signifying that the second heat management loop L2 can also function in the cold mode and the warm mode.

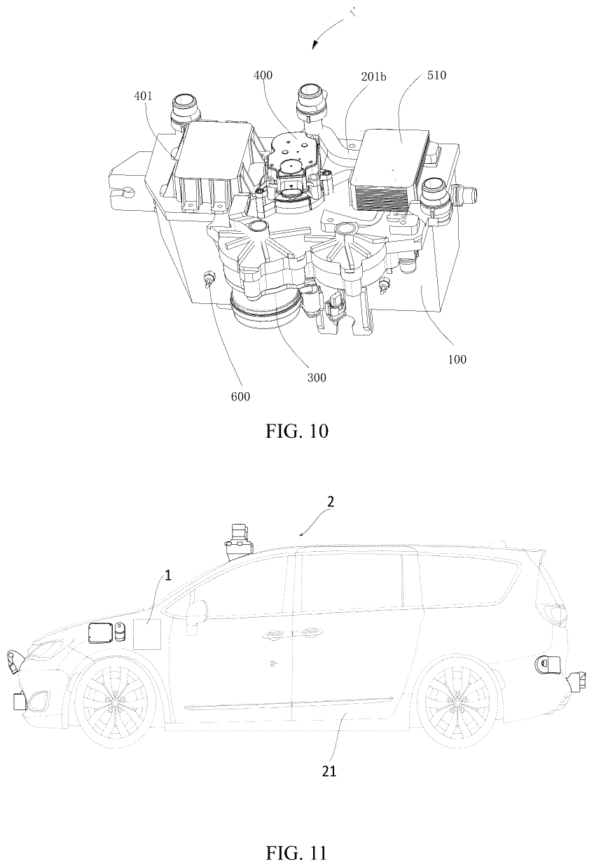

Referring to FIG. 10, in some embodiments of the vehicle thermal management system 1, the heat exchanger assembly 500 only includes the refrigeration heat exchanger 510, as shown in FIG. 10 of the vehicle thermal management system 1′. This configuration indicates that the first thermal management loop L1 and the second thermal management loop L2 of the vehicle thermal management system 1′ are in a single cooling mode. Specifically, the vehicle thermal management system 1 found in the original vehicle thermal management system 1 has been replaced with a sealing component 401 in the vehicle thermal management system 1′, thereby retaining the refrigeration heat exchanger 510 and achieving diversified design of heat exchange modes.

It can be understood that in some embodiments, the heat exchanger assembly 500 can also be omitted, meaning that the liquid does not need to be heated or cooled by the heat exchanger to manage the temperature control device, but directly manages the temperature control device based on the temperature of the liquid itself.

The vehicle thermal management system 1 also includes one or more liquid level sensors 600 and alarms.

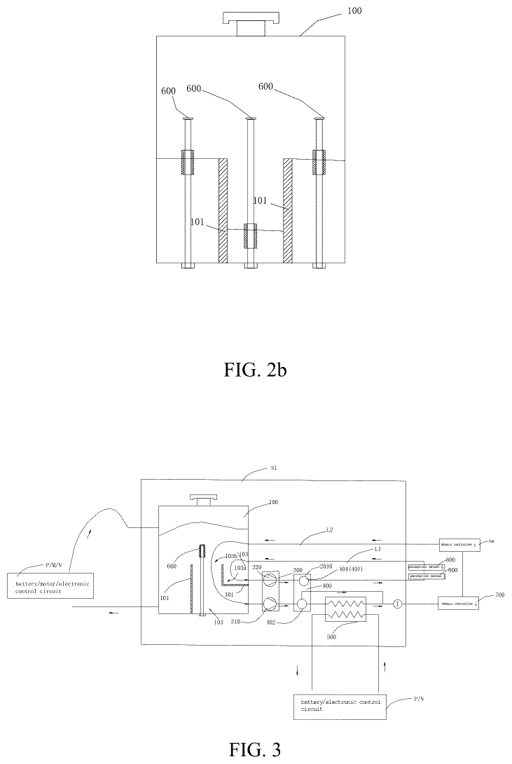

Refer to FIG. 2a, an internal schematic diagram of the water tank 100 is illustrated. In this embodiment, a liquid level sensor 600 is installed inside the water tank 100 for sensing the liquid level in each chamber 103. Specifically, when the liquid level value sensed by the liquid level sensor 600 is within the first liquid level range, it indicates that there is no liquid leakage in the first thermal management loop L1 and the second thermal management loop L2. When the liquid level sensor detects that the liquid level value is within the second liquid level range, it indicates that there is no liquid leakage in either the first thermal management loop L1 or the second thermal management loop L2, triggering an alarm (not shown in the figure) and emits a first alarm. The liquid level value sensed by the liquid level sensor 600 is within the third liquid level range, and leakage is detected in both the first thermal management loop L1 and the second thermal management loop L2, triggering an alarm to emit a second alarm. Among them, a value of the first liquid level range is greater than a value of the second liquid level range, and the value of the second liquid level range is greater than the range of the third liquid level value. That is to say, by using a liquid level sensor 600, can be detected for leakage, saving devices.

Referring to FIG. 2b, in some feasible embodiments, each chamber 103 receives a liquid level sensor 600 to sense the liquid level of the corresponding chamber 103. Among them, when the liquid level values sensed by the liquid level sensor 600 are within the first liquid level range, it is determined that there is no liquid leakage in the first thermal management loop L1 and the second thermal management loop L2. When one of the two liquid level sensors 600 senses a liquid level value that is within the first liquid level range, and the other senses a liquid level value that is lower than the first liquid level range, this indicates a leak in one of the first thermal management loop L1 and the second thermal management loop L2. In this case, a first alarm is triggered to alert of the potential issue. Furthermore, when both liquid level sensors 600 sense liquid level values that are lower than the first liquid level range, it is detected that leakage has occurred. This triggers a second alarm, which is typically more severe than the first alarm, to ensure safety redundancy and prompt immediate attention.

In this embodiment, the first group of components requiring temperature control is exemplified as the domain controller 700, while the second group of temperature controlled components serves as the perception sensor 800 for illustrative purposes. The domain controller 700 has a first predetermined working temperature threshold, which includes a first predetermined upper working temperature threshold and a first predetermined lower working temperature threshold. When the temperature of domain controller 700 is lower than the first preset lower limit threshold of operating temperature, it is necessary to heat the domain controller 700, in which case the heating heat exchanger 520 is activated; Conversely, when the temperature of the domain controller 700 exceeds the first predetermined upper temperature threshold, it is necessary to cool the domain controller 700, that is, the refrigeration heat exchanger 510 is engaged for this purpose.

The perception sensor 800 has a second predetermined working temperature threshold, which includes a second predetermined upper working temperature threshold and a second predetermined working temperature threshold. When the temperature of the perception sensor 800 is below the second predetermined working temperature threshold, it is necessary to heat the perception sensor 800, that is, the heating heat exchanger 520 is working; When the temperature of the perception sensor 800 exceeds the second predetermined working temperature upper limit threshold, it is necessary to cool the perception sensor 800, that is, the refrigeration heat exchanger 510 works.

In the above embodiments, the vehicle thermal management system 1 can be configured according to actual needs in specific applications, that is, the vehicle thermal management system 1 can also allow users to configure multiple types of vehicle thermal management systems. Below are several implementation examples to illustrate how the vehicle thermal management system 1 can achieve diversified configurations.

Referring to FIG. 3, an internal schematic diagram of the first embodiment of the vehicle thermal management system is illustrated. In this embodiment, the vehicle thermal management system S1 includes the first thermal management loop L1 and the second thermal management loop L2. Both of the first thermal management loop L1 and the second thermal management loop L2 are functional. The first group of components requiring temperature control consists of perception sensor 1 . . . perception sensor N, while the second group of components requiring temperature control includes electronic control circuit 1 . . . electronic control circuit N. The vehicle thermal management system S1 only includes a refrigeration heat exchanger 510 and a liquid level sensor 600. Notably, the refrigeration heat exchanger 510 is exclusively installed within the first thermal management loop L1.

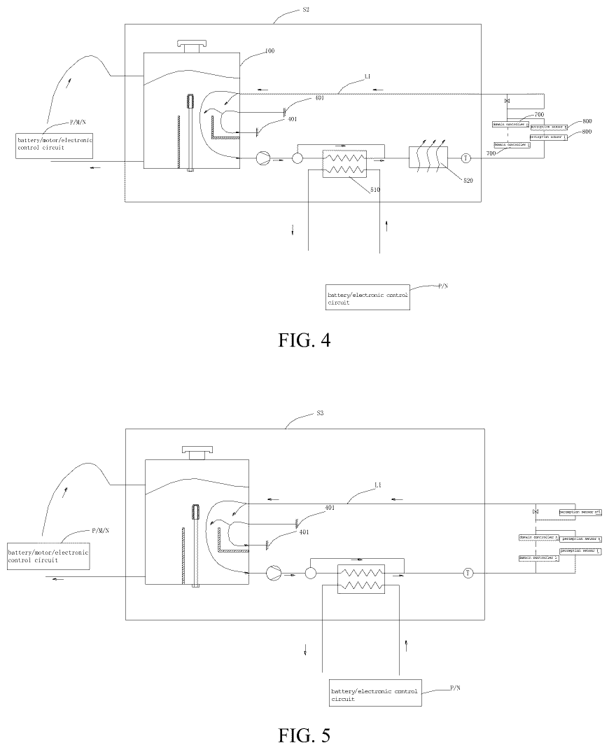

Referring to FIG. 4, an internal schematic diagram of a vehicle thermal management system S2 of a second embodiment is illustrated. A key difference between vehicle thermal management system S2 and vehicle thermal management system S1 is that vehicle thermal management system S2 lies in the inclusion of both a refrigeration heat exchanger 510 and a heating heat exchanger 520. This allows the first thermal management loop L1 to perform both cooling and heating functions. In contract, the second thermal management loop L2 within the vehicle thermal management system S2 is deactivated, effectively rendering it non-functional, leaving only the first thermal management loop L1 operational. The first thermal management loop L1 serves to regulate the temperature of both the first group of the components requiring temperature control and second group of the components requiring temperature control, providing either cooling or heating as required.

Referring to FIG. 5, an internal schematic diagram of the vehicle thermal management system S3 of a third embodiment. A key difference between the vehicle thermal management system S3 and the vehicle thermal management system S1 lie in the fact that the second thermal management loop L2 in vehicle thermal management system S3 is deactivated, rendering it non-functional and leaving only the first thermal management loop L1. The first thermal management loop L1 is responsible for cooling both the first group of the components requiring temperature control and the second group of the components requiring temperature control.

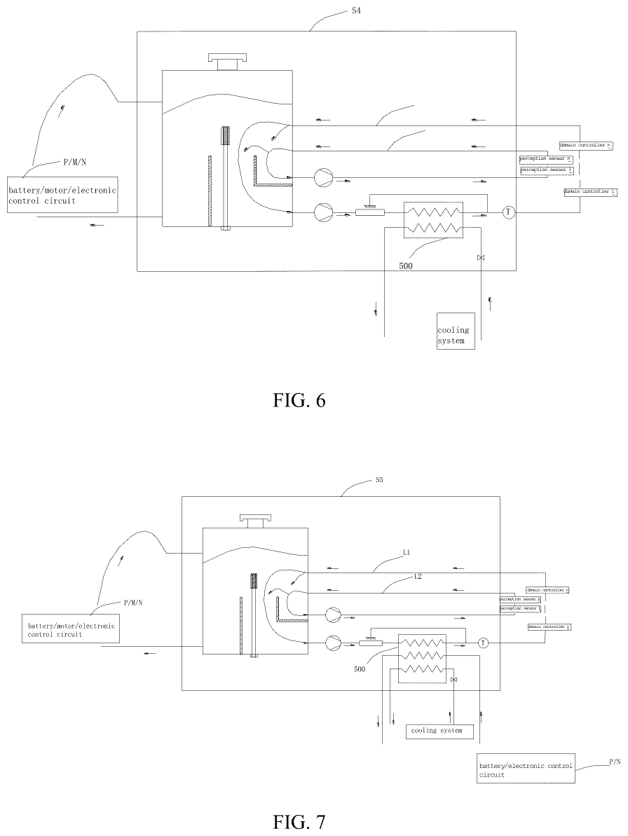

Referring to FIG. 6, an internal schematic diagram a vehicle thermal management system S4 of a fourth embodiment. A key difference between the vehicle thermal management system S4 and the vehicle thermal management system S3 is that the first thermal management loop L1 and the thermal management loop L2 in the vehicle thermal management system S4 are operational, and the heat exchanger assembly 500 of the vehicle thermal management system S4 employs a water refrigeration heat exchanger.

Refer to FIG. 7, an internal schematic diagram of a vehicle thermal management system S5 of a fifth embodiment. A key difference between the vehicle thermal management system S5 and the vehicle thermal management system S4 is that the heat exchanger assembly 500 of the vehicle thermal management system S5 employs a plurality of the channel heat exchanger.

From the above embodiments, it is evident that when the vehicle thermal management system 1 allows for the utilization of the first thermal management loop L1 and/or the second thermal management loop L2, depending on actual requirements. Concurrently, the heat exchanger assembly 500 can be configured for single cooling, single heating, and cold-heating modes, as well as adjusted to accommodate to single and multiple channels. In addition, different media such as refrigerant water or pure water can be employed as the coolant. Consequently, the vehicle thermal management system described in the above embodiments impart greater flexibility and versatility to thermal management methods, enabling the implementation of a “full liquid cooling scheme” or “partial liquid cooling scheme” for autonomous driving, while also fulfilling the need for multi-configuration management.

Referring to FIG. 11, a schematic diagram of an autonomous vehicle 2 with the above vehicle management system. The. Autonomous vehicle 2 includes a vehicle body 21 and the vehicle thermal management system 1 installed on the vehicle body 21. The structure of the vehicle thermal management system 1 can be found in the description of the vehicle thermal management system 1 above, and will not be further elaborated here.

Obviously, technical personnel in this field can make various modifications and variations to the present application without departing from the spirit and scope of the present application. In this way, if these modifications and variations of the present application fall within the scope of the claims and their equivalent technologies, the present application also intends to include these modifications and variations.

The above listed examples are only the preferred embodiments of this application, and of course, they cannot be used to limit the scope of the rights of this application. Therefore, the equivalent changes made according to the claims of this application still fall within the scope of this application.

What is claimed is:

1. A vehicle thermal management system for components requiring temperature control, the components requiring temperature control comprising a first group of components requiring temperature control, and a second group of components requiring temperature control, the vehicle thermal management system comprising:
a water tank with a plurality of chambers, comprising a first chamber and a second chamber filled with liquid;
a flow channel plate with a plurality of channels connected to the chambers, forming thermal management loops, the thermal management loops comprising a first thermal management loop and a second thermal management loop to respectively control the first group of the components and the second group of the components;
a power assembly with a first power component and a second power component. respectively arranged on the first thermal management loop and the second thermal management loop, to pump liquid from the corresponding chambers into the first thermal management loop and/or the second thermal management loops; and
a flow channel control assembly with a first flow channel control component and a second flow channel control component, respectively arranged on the first thermal management loop and the second thermal management loop, enabling selective activation and deactivation of the first thermal management loop and the second thermal management loop.

2. The vehicle thermal management system according to claim 1, further comprising a heat exchanger assembly, the heat exchanger assembly comprising a first heat exchanger and a second heat exchanger, respectively arranged on the first thermal management loop and the second thermal management loop to exchange heat with the liquid in the first management channel and the second thermal management channel.

3. The vehicle thermal management system according to claim 1, wherein each of the first thermal management loop and the second thermal management loop has a plurality of control ports, and the flow channel control assembly is configured to control on-off status of the first thermal management loop and second thermal management loop.

4. The vehicle thermal management system according to claim 3, wherein the flow control assembly further comprises valve switches installed on the plurality of the control ports to be controlled to open and close during the operation of the thermal management system.

5. The vehicle thermal management system according to claim 4, wherein each of the valve switches in the first thermal management loop or the second thermal management loop is in a normally closed state.

6. The vehicle thermal management system according to claim 3, wherein the flow control assembly further comprises blocking components, which are blocked at the control ports, causing one of the first thermal management loop and the second thermal management loop to be shut off.

7. The vehicle thermal management system according to claim 1, wherein the plurality of the flow channels include a main flow channel and a branch flow channel, the main flow channel is located below a liquid level of the water tank, and the liquid flows from the main flow channel to the branch flow channel.

8. The vehicle thermal management system according to claim 1, wherein a gap is formed between the plurality of the chambers and the water tank, and each chamber or only one chamber receives one liquid level sensor to detect whether the first thermal management loop and second thermal management loop are experiencing leaking liquid.

9. The vehicle thermal management system according to claim 1, further comprising an alarm, when only one chamber is received the liquid level sensor, a liquid level value sensed by the liquid level sensor is within a first liquid level range, and it is detected that there is no liquid leakage in the first thermal management loop and the second thermal management loops; when liquid level value is within a second liquid level range, it is detected that there is a leakage in either the first thermal management loop or the second thermal management loop, and the alarm is triggered to emit a first alarm; when the liquid level value is within a third liquid level range, it is detected that there is leakage in both the first and second thermal management loops, and the alarm is triggered to emit a second alarm; the value of the first liquid level range is greater than the value of the second liquid level range, and the value of the second liquid level range is greater than the range of the third liquid level value.

10. The vehicle thermal management system according to claim 1, wherein the first group of the components requiring temperature control and the second group of the components requiring temperature control have different predetermined working temperature thresholds.

11. The vehicle thermal management system according to claim 1, wherein each of the predetermined working temperature thresholds includes a predetermined working temperature threshold and a predetermined upper working temperature threshold; when the temperature of the components requiring temperature control reaches predetermined working temperature threshold, the components requiring temperature control is cooled through the heat exchanger assembly; when the temperature of the components requiring temperature control reaches the lower limit threshold of the predetermined working temperature, the components requiring temperature control is heated through the heat exchanger assembly.

12. An autonomous driving vehicle, comprising:
a vehicle body;
components requiring temperature control comprising a first group of components requiring temperature control, and/or components requiring temperature control; and
a vehicle thermal management system, comprising:
a water tank with a plurality of chambers, comprising a first chamber and a second chamber filled with liquid;
a flow channel plate with a plurality of channels connected to the chambers, forming thermal management loops, the thermal management loops comprising a first thermal management loop and a second thermal management loop to respectively control the first group of the components and the second group of the components;
a power assembly with a first power component and a second power component. respectively arranged on the first thermal management loop and the second thermal management loop, to pump liquid from the corresponding chambers into the first thermal management loop and/or the second thermal management loops; and
a flow channel control assembly with a first flow channel control component and a second flow channel control component, respectively arranged on the first thermal management loop and the second thermal management loop, enabling selective activation and deactivation of the first thermal management loop and the second thermal management loop.

13. The autonomous driving vehicle according to claim 12, further comprising a heat exchanger assembly, the heat exchanger assembly comprising a first heat exchanger and a second heat exchanger, the first heat exchanger and second heat exchanger being respectively arranged on the first thermal management loop and the second thermal management loop to exchange heat with the liquid in the first management channel and the second thermal management channel.

14. The autonomous driving vehicle according to claim 12, wherein each of the first thermal management loop and the second thermal management loop has a plurality of control ports, and the flow channel control assembly is configured to control the control ports to on-off status of the first thermal management loop and second thermal management loop.

15. The autonomous driving vehicle of 13, wherein the flow control assembly further comprises valve switches installed on the plurality of the control ports to be controlled to open and close during the operation of the thermal management system.

16. The vehicle thermal management system according to claim 15, wherein each of the valve switches in the first thermal management loop or the second thermal management loop is in a normally closed state.

17. The autonomous driving vehicle according to claim 13, wherein the flow control assembly further comprises blocking components, which are blocked at the control ports, causing one of the first thermal management loop and the second thermal management loop to be shut off.

18. The autonomous driving vehicle according to claim 12, wherein the plurality of the flow channels include a main flow channel and a branch flow channel, the main flow channel is located below a liquid level of the water tank, and the liquid flows from the main flow channel to the branch flow channel.

19. The autonomous driving vehicle according to claim 12, wherein a gap is formed between the plurality of the chambers and the water tank, and each chamber or only one chamber receives one liquid level sensor to detect whether the first thermal management loop and second thermal management loop are experiencing leaking liquid.

20. The autonomous driving vehicle according to claim 19, wherein the vehicle thermal management system comprises an alarm, when only one chamber is received the liquid level sensor, a liquid level value sensed by the liquid level sensor is within a first liquid level range, and it is detected that there is no liquid leakage in the first thermal management loop and the second thermal management loops; when liquid level value is within a second liquid level range, it is detected that there is a leakage in either the first thermal management loop or the second thermal management loop, and the alarm is triggered to emit a first alarm; when the liquid level value is within a third liquid level range, it is detected that there is leakage in both the first and second thermal management loops, and the alarm is triggered to emit a second alarm; the value of the first liquid level range is greater than the value of the second liquid level range, and the value of the second liquid level range is greater than the range of the third liquid level value.
